(19) United States
(12) Patent Application Publication
(10) Pub. No.: US 2010/0018857 A1
(43) Pub. Date: Jan. 28, 2010

(54) SPUTTER CATHODE APPARATUS ALLOWING THICK MAGNETIC TARGETS

(75) Inventors: Paul Stephen McLeod, Berkeley, CA (US); Larry Dowd Hartsough, Berkeley, CA (US)

Correspondence Address: Shumaker & Sieffert, P.A., 1625 Radio Drive, Suite 300, Woodbury, MN, 55125, US

(73) Assignee: Seagate Technology LLC, Scotts Valley, CA (US)

(21) Appl. No.: 12/178,446

(22) Filed: Jul. 23, 2008

(51) Int. Cl. C23C 14/35

(52) U.S. Cl. 204/298.19

(57) ABSTRACT

A sputtering apparatus allowing thick targets and method of making the same. The apparatus includes a sputtering target with a glow discharge plasma formed thereon during sputtering. The sputtering target is disposed in a plane, with a front of the plane defined as the side on which the glow discharge plasma is located during sputtering and a back of the plane defined as the opposite side. The sputtering apparatus also includes a magnetic circuit with an electrically floating center pole and an electrically floating outside pole. Both the center pole and outside pole are at least partially disposed on the front side of the plane defined by the sputtering target.

### BACKGROUND

One key component of any computer system is a device to store data. Computer systems have many different places where data can be stored. One common place for storing massive amounts of data in a computer system is on a disc drive. The most basic parts of a disc drive are an information storage disc that is rotated, an actuator that moves a transducer to various locations over the disc, and electrical circuitry that is used to write and read data to and from the disc. The disc drive also includes circuitry for encoding data so that it can be successfully retrieved and written to the disc surface. A microprocessor controls most of the operations of the disc drive as well as passing the data back to the requesting computer and taking data from a requesting computer for storing to the disc.

In the disc drive industry, high-performance, thin-film storage discs produced by depositing successive layers on a substrate apparatus for preparation of such storage discs are well known in the art. For storage discs of the type formed on a rigid disc substrate, each layer in the storage disc may deposited in a separate chamber. For example, the under-layer, the magnetic layer, and the over-layer (lubrication layer) are

generally deposited in separate processing chambers. Generally, such layers are deposited onto the disc surfaces using sputtering processes.

Sputtering is a well known method of providing relatively uniform deposits of material on a substrate. Essentially, sputtering is accomplished by the impingement of gas ions on a cathode plate or target plate in the presence of an electrostatic field which causes particles of the cathode plate material to be dislodged therefrom. By appropriately positioning a substrate in the path of such dislodged particles, a deposit of cathodic material will be produced on the substrate. In a typical sputtering system the target (cathode) and substrate holder (anode) are positioned so that the surface of the substrate upon which the film is to be deposited is placed on the holder, facing the target.

Increased sputtering rates are achieved by confining electrons of the glow discharge plasma, in which the gas ions are produced, in close proximity to the target plate, such that ionization of the gas will occur more frequently. In this manner, an increased rate of ion impingement upon a target plate, and hence greater sputtering activity, is enabled. More specifically, a magnetic field is provided such that flux lines extend from and return in an arched or curved path to the surface of a target plate thereby forming a virtual “tunnel”. By providing the aforementioned magnetic field in a closed loop or “racetrack” configuration, electrons will tend to be swept about this loop under the influence of the applied magnetic field and electric field. It is the resulting plasma confinement which promotes a high degree of ionization of molecules of the ambient gas, e.g. argon. The ions are electrostatically attracted to the target plate and thus effectively stimulate a high degree of sputtering activity and correspondingly high deposition rates of cathodic, or sputtered, material on a substrate.

Material sputtered from a target plate subjected to the aforedescribed magnetic field is dislodged primarily from an erosion region underlying the curved flux lines. In addition, the region that exists at which such flux lines are parallel to the cathode traps the electrons most efficiently. This, in turn results in maximum target erosion at a region substantially aligned with and underlying the foregoing area over which magnetic flux lines are parallel to the target plate. When a complete target plate area is considered, it has been found that a line defining the nadir of a deep “valley” exists in the cathode plate approximately centrally of the aforementioned closed magnetic loop. Accordingly, erosion of the cathode or target occurs along the “racetrack,” leaving the center and the edges of the target intact on the cathode, rather than being deposited on the substrate. This is disadvantageous, as usually only approximately a third of the target material can be utilized for deposition on the substrate. A planar cathode with an area of erosion in the form of a racetrack configuration is shown in FIG. 1.

Systems such as that described above, wherein the target is a plate material are called planar magnetron sputtering systems. In addition to the low target utilization, planar magnetron targets also have other limitations. While portions of the targets are not sputtered, they are collecting sputtered atoms from the sputtered areas that are backscattered from collisions with the sputtering gas. Over time, the films that collect on the non-sputtered areas build up and also react with ambient gases other than the inert sputter gas that are always present in an imperfect vacuum. Since the ambient gases are typically reactive; e.g. H₂O, N₂, O₂ CO₂, the deposits tend to be insulative and therefore collect charges from the discharge. When the charge is sufficient, arcing occurs; either to the chamber walls or through the insulative films to the target. Arcing causes local heating and vaporization; i.e. small explosions which often eject particles onto the substrate thereby causing defects in the coatings being deposited. Even if no arcing occurs the films that build up are often highly stressed and tend to exfoliate also causing film defects.

Accordingly, there is a need for a planar magnetron sputtering system with high target utilization and more even distribution of the utilization. Such a system would allow an increase in the thickness of targets and also increase the yield of each target, thereby reducing costs and increasing efficiency.

### SUMMARY

In an embodiment, the present invention provides a sputtering apparatus allowing thick targets. The invention includes a sputtering target with a glow discharge plasma formed thereon during sputtering. The sputtering target is disposed in a plane, with a front of the plane defined as the side on which the glow discharge plasma is located during sputtering and a back of the plane defined as the opposite side. The sputtering apparatus also includes a magnetic circuit with an electrically floating center pole and an electrically floating outside pole. Both the center pole and outside pole are at least partially disposed on the front side of the plane defined by the sputtering target.

In another embodiment, the present invention provides a method of forming a sputtering apparatus. The method includes providing a ring-shaped target it a plane with a front side and a back side, such that the front side is defined as that which a glow discharge plasma is formed during sputtering. The method also includes providing a magnetic element in the vicinity of the ring-shaped target to form a magnetic circuit. The magnetic circuit includes an electrically floating outside pole and an electrically floating inside pole. Both the outside pole and the inside pole are at least partially disposed on the front side of the plane defined by the sputtering target.

### BRIEF DESCRIPTION OF THE DRAWINGS

As will be realized, this invention is capable of other and different embodiments, and its details are capable of modifications in various obvious respects, all without departing from this invention. Accordingly, the drawings and description are to be regarded as illustrative in nature and not as restrictive.

The invention is described herein with respect to an exemplary embodiment and drawings, in which:

FIG. 1 is a perspective view of a planar magnetron sputtering target with erosion in a racetrack configuration.

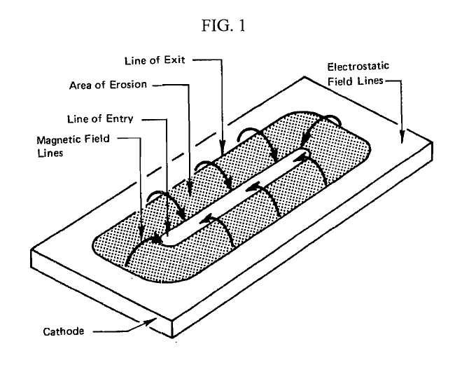

FIG. 2 is a perspective view of an embodiment of the present invention.

FIG. 3 is a cross-sectional view taken along line 3-3 of the embodiment shown in FIG. 2.

### DETAILED DESCRIPTION

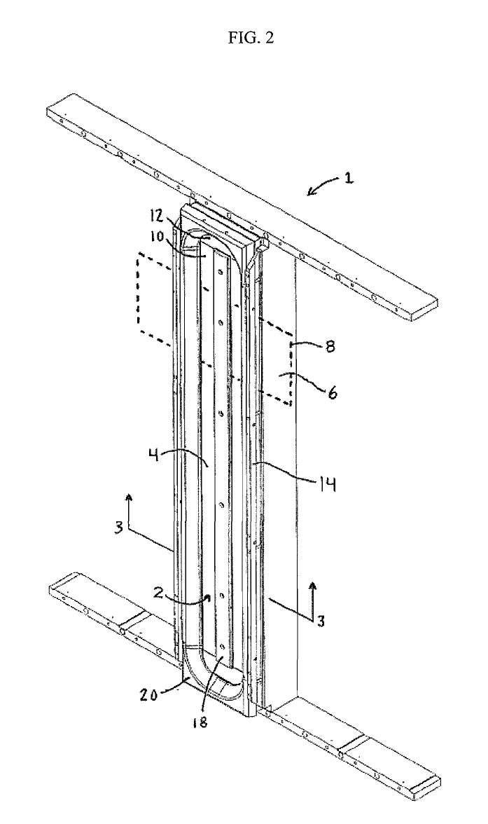

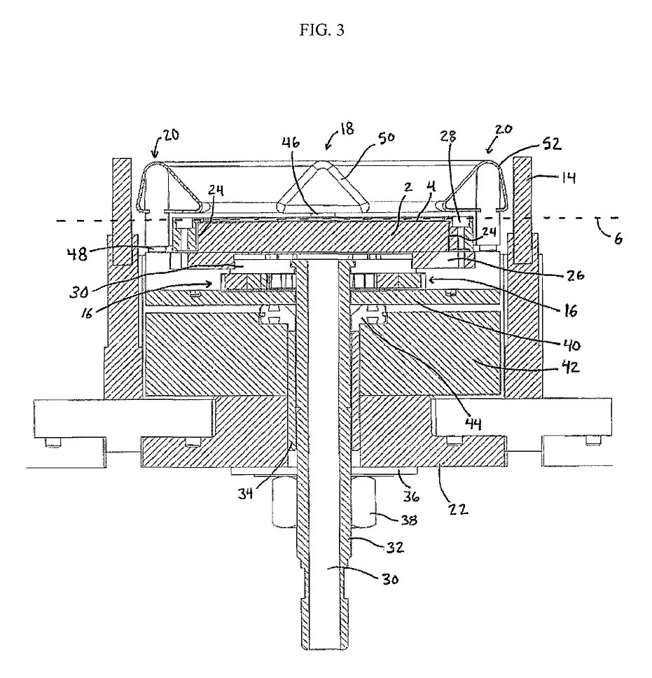

FIG. 2 shows a sputtering apparatus 1 in accordance with the present invention. The sputtering apparatus includes a ring shaped target 2 that is substantially disposed in a plane 6 defined by the orientation of a front surface 4 of the ring shaped target. A small section 8 of the plane 6 is shown in FIG. 2 for illustrative purposes. In the embodiment shown in the drawings, the front surface 4 of the target 2 is flat, and the plane is congruent with the front surface 4 of the target 2. However, it is not necessary that the front surface 4 of the target be flat. In fact, as the target is utilized for sputtering, portions of it will erode over time. As a result, even an originally flat target 2 will not retain this characteristic. Accordingly, the plane 6 is not necessarily defined by a specific dimension of the target 2 or sputtering apparatus 1. In one embodiment, the plane may pass through either side 24 of the target 2 (shown in FIG. 3).

In the illustrated embodiment, the target 2 is embodied as having an elongate ring configuration. The ring shaped target 2 may be formed of a single ring shaped target piece or, as illustrated, may be formed of different sections 10, 12 of target material. For example, the illustrated embodiment includes two elongate sections 10 and two end sections 12 which complete the ring configuration. Although shown as being elongate, the sputtering apparatus and target included therein can have alternative configurations.

The sputtering target 2 of the present invention is utilized as a cathode by coupling the target 2 to a voltage source. The sputtering apparatus of the present invention may also include at least one anode 14. In the embodiment shown in FIG. 2, the sputtering apparatus includes anodes 14 on both elongate sides of the sputtering apparatus.1. During sputtering, a voltage potential is coupled across the cathode target 2 and the anode 14. As a result, during use a glow discharge plasma forms in front of the target and particles of the target material are sputtered onto a substrate, for example a magnetic recording media.

The sputtering apparatus 1 of the present invention also includes a magnetic circuit to help confine electrons of the glow discharge plasma, thereby increasing the rate of sputtering. The magnetic circuit may be formed by a magnetic element 16 (shown in FIG. 3) along with ferri- or ferromagnetic elements. As shown in FIG. 2, the magnetic circuit includes a center magnet pole 18 and an outer magnet pole 20. The center magnet pole 18 can have a first magnetic polarization while the outer magnet pole has a second and opposite magnetic polarization. Each of the center magnet pole 18 and outer magnet pole 20 are at least partially disposed on the front side of plane 6. Because the center magnet pole 18 and outer magnet pole 20 extend to the front side of pane 6, the target 2 is not a fundamental element in the magnetic circuit. As a result, the magnetic field in front of the target 2 is increased. Further, this allows the use of non-magnetic materials as part of the target 2. In addition to using non-magnetic materials, having the magnetic field strength increased in front of the target allows the use of thicker targets. Thicker targets yield higher production rates and more efficient target utilization.

In addition to forming part of the magnetic circuit, center magnet pole 18 and outer magnet pole 20 may also be electrically isolated from the other elements of the sputtering apparatus 1, such that they are electrically floating. In an embodiment where the center magnet pole 18 and outer magnet pole 20 are electrically floating, the sputtering apparatus of the present invention provides additional advantages for containing the electrons of the glow discharge plasma. When a glow discharge plasma is formed during the sputtering process, the magnet poles 18, 20 are initially bombarded by electrons from the plasma. Because the magnet poles 18, 20 are electrically floating, there is no path for any charge build up on the magnet poles to escape. Accordingly, the magnet poles 18, 20 become negatively charged. During sputtering, the electrons within the glow discharge plasma are repelled from the negatively charged magnet poles 18, 20. This helps contain the electrons of the glow discharge plasma on the front surface of the target 2 in a dense plasma. The confined glow discharge plasma increases efficiency of the sputtering apparatus and helps yield higher target utilization.

Additional details of the aforedescribed embodiment of the invention are more easily understood with reference to the cross-sectional view shown in FIG. 3. The sputtering apparatus 1 shown in FIG. 3 is depicted as being held within a sputtering chamber. Although the entirety of the sputtering chamber is not shown, the chamber wall 22 is included. The target 2 is arranged substantially opposite the chamber wall 22 and such that a glow discharge plasma is directed away from the chamber wall 22. The target 2 is disposed in a plane 6. As described above with respect to FIG. 2, the front 4 of the target 2 is shown as being even with the plane 6. However, the target 2 could be arranged in alternative configurations with respect to the plane 6. For example, the plane 6 could pass through both sides 24 of the target 2.

The target 2 of the sputtering apparatus is supported by a cooling block 26. A target clamp 28 disposed on the outside of the target 2 holds target 2 securely on the cooling block 26. Target cooling water 30 is fed to the cooling block 26 through a water line 32 to keep the target 2 at an acceptable operating temperature. The water line 32 brings cooling water 30 to the target 2 from outside the sputtering chamber. A water line insulator 34 is used to insulate the water line 32 from the chamber wall 22 at the entry point of the water line 32 into the sputtering chamber behind the target 2. The water line 32 is stabilized with a washer 36 and a water line retaining nut 38 on the outside of the chamber wall 22.

Much of the magnetic circuit of the sputtering apparatus lies behind the cooling block 26. In the illustrated embodiment the magnetic circuit is formed by the magnetic element 16. The magnetic element 16 may have several different embodiments. Such as that shown in FIG. 3, the magnetic element 16 may be formed of a plurality of permanent magnets. Alternatively, the magnetic element 16 could also be formed by a plurality of electromagnetic elements. Further still, the magnetic element 16 could be formed of a single magnetic constituent, either permanent or electromagnetic. In this embodiment, the magnetic element 16 forms the basis for the magnetic circuit which also includes the center magnet pole 18 and the outer magnet pole 20. Although the outer magnet pole 20 is clearly depicted here as two pieces, one on the left and one on the right, the outer magnet pole 20 may be formed as a ring surrounding the target 2. In such an embodiment, the FIG. 3 would merely be showing left and right sides of the outer magnet pole 20, and not separate and distinct elements. Of course, the outer magnet pole 20 may still be comprised of several elements. As stated above, the extension of the outer and center magnet poles 18, 20 to the front side of plane 6 helps avoid inclusion of the target 2 in the magnetic circuit. As a result, this yields higher target utilization and allows both ferromagnetic and non-magnetic materials to be sputtered using the sputtering apparatus of the invention.

The magnetic element 16, as well as the center and outer magnet poles 18, 20, are held in place by a magnet support plate 40. In turn, the magnet support plate is separated from a support block 42 that is adjacent the sputtering chamber wall 22 by insulating body 44. The insulating body 44 is formed by a combination of an insulator and O-rings.

A pair of anodes 14 is placed outside the outer magnet pole 20. During sputtering, the anodes 14 are coupled to the voltage source, thereby forming a glow discharge plasma on the front surface of the target cathode 2. Accordingly, the material of target 2 can be sputtered onto a substrate placed within the vicinity of target 2. Using this method, layers of both magnetic and non-magnetic materials can be precisely sputtered on to various substrates, such as magnetic recording media.

To aid effectiveness of the sputtering apparatus 1, the outer magnet pole 20 and center magnet pole 18 are both electrically isolated from the rest of the apparatus 1. As shown, a center pole insulator 46 is positioned between the center pole 18 and the remainder of the apparatus. Similarly, outer pole insulators 48 are positioned between the outer pole 20 and the remainder of the magnetic circuit. The pole insulators 46 and 48 do not, in fact, insulate the magnet poles 18, 20. Instead, they simply electrically isolate the poles from the rest of the apparatus. As a result, the outer and center magnet poles 20, 18, are electrically floating and are able to vary in charge. This provides a advantage for the present invention, as stated above. During sputtering, the floating outer pole 20 and center pole 18 will be bombarded by electrons that have no discharge path from the poles. As the electrons continued to collide with the poles they become negatively charged and begin to repel other electrons within the glow discharge plasma. Because the center pole 18 and outer pole 20 substantially surround the target 2, the center pole and outer pole 20 help contain the plasma by confining the electrons therein.

As shown in the illustrated embodiment, the center pole 18 and the outer pole 20 may be covered with a center magnet shield 50 and outer magnet shield 52, respectively. The magnet shields 50, 52 may become part of the magnetic circuit and help to direct the circuit in a desired direction. Further, the magnet shields 50, 52 may be used to shield certain elements of the sputtering apparatus from the glow discharge plasma. For example, the outer magnet shield 52 is shown in the illustrated embodiment covering target clamps 28. This allows the target clamps to be metallic without substantially interfering with the operation of the sputtering apparatus.

Only the preferred embodiments of the present invention and but a few examples of its versatility are shown and described in the present disclosure. It is to be understood that the present invention is capable of use in various other combinations and environments and is susceptible of changes and/or modifications within the scope of the inventive concept as expressed herein.

We claim:

1. A sputtering apparatus comprising:
a target disposed in a plane and defining a front side of the plane in which a glow discharge plasma is located during sputtering and a back side of the plane;
an electrically floating outside pole forming part of a magnetic circuit, the electrically floating outside pole having a first polarity and being at least partially disposed on the front side of the plane; and
an electrically floating center pole forming another part of the magnetic circuit, the electrically floating center pole having a second polarity and being at least partially disposed on the front side of the plane.

2. The sputtering apparatus of claim 1 further comprising a voltage source electrically connected to the target.

3. The sputtering apparatus of claim 2 further comprising an outside insulator disposed between the electrically floating outside pole and the voltage source.

4. The sputtering apparatus of claim 2 further comprising a center insulator disposed between the electrically floating center pole and the voltage source.

5. The sputtering apparatus of claim 1 wherein the target is a cathode.

6. The sputtering apparatus of claim 1 further comprising a magnetic element that defines the magnetic circuit and is coupled to the electrically floating center pole and electrically floating outside pole.

7. The sputtering apparatus of claim 1 further comprising an outside floating shield adjacent the electrically floating outside pole.

8. The sputtering apparatus of claim 1 further comprising a center floating shield adjacent the electrically floating center pole.

9. The sputtering apparatus of claim 6 wherein the magnetic element is disposed on the back side of the plane.

10. The sputtering apparatus of claim 1 further comprising at least one target clamp adjacent to the ring-shaped target.

11. The sputtering apparatus of claim 10 further comprising an outside floating shield adjacent the electrically floating outside pole and covering the target clamp.

12. A method of forming a sputtering apparatus comprising:
providing a ring-shaped target in a plane, the plane having a front side in which a glow discharge plasma is located during sputtering and a back side;
providing a magnetic element in the vicinity of the ring-shaped target thereby forming a magnetic circuit;
providing an electrically floating outside pole in the magnetic circuit, the electrically floating outside pole having a first polarity and being at least partially disposed on the front side of the plane; and
providing an electrically floating center pole in the magnetic circuit, the electrically floating center pole having a second polarity and being at least partially disposed on the front side of the plane.

13. The method of claim 12 further comprising coupling a voltage source electrically to the ring-shaped target.

14. The method of 13 further comprising disposing an outside insulator between the electrically floating outside pole and the voltage source.

15. The method of 13 further comprising disposing a center insulator between the electrically floating center pole and the voltage source.

16. The method of claim 12 wherein the ring-shaped target is coupled to the voltage source such that it is a cathode.

17. The method of claim 12 further comprising providing an outside floating shield adjacent the electrically floating outside pole.

18. The method of claim 12 further comprising providing a center floating shield adjacent the electrically floating center pole.

19. The method of claim 12 wherein the magnetic element is provided on the back side of the plane.

20. The method of claim 12 further comprising anchoring the ring-shaped target with a target clamp and covering the target clamp with an electrically floating outside shield adjacent the electrically floating outside pole.
